(19) United States
(12) Patent Application Publication
(10) Pub. No.: US 2018/0013195 A1
(43) Pub. Date: Jan. 11, 2018

(54) Earpiece with laser induced transfer of PVD coating on surfaces

(71) Applicant: BRAGI GmbH, Munchen (DE)

(72) Inventors: Nikolaj Hviid, Munchen (DE); Peter Vincent Boesen, Munchen (DE)

(73) Assignee: BRAGI GmbH, Munchen (DE)

(21) Appl. No.: 15/635,755

(22) Filed: Jun. 28, 2017

Related U.S. Application Data
(60) Provisional application No. 62/359,048, filed on Jul. 6, 2016.

(51) Int. Cl. H01Q 1/38; C23C 14/22; H01Q 1/22; H01Q 9/04

(52) U.S. Cl. CPC H01Q 1/38; H01Q 1/22; H04B 1/385; C23C 14/22; H04B 2001/3866; H01Q 9/0421

(57) ABSTRACT

An earpiece includes an earpiece housing having an external surface and an internal surface, a transceiver disposed within the earpiece, and an antenna deposited onto a surface of the earpiece housing and operatively connected to the transceiver, wherein the antenna is deposited onto the surface of the earpiece housing using a vapor deposition process. A method of manufacturing a wearable device includes loading a conductive substance into a vapor deposition system and depositing the conductive substance onto a surface of a wearable device using the vapor deposition system to form an antenna pattern.

### PRIORITY STATEMENT

This application claims priority to U.S. Provisional Patent Application 62/359,048, filed on Jul. 6, 2016, and entitled Earpiece with laser induced transfer of PVD coating on surfaces, hereby incorporated by reference in its entirety.

### FIELD OF THE INVENTION

The present invention relates to wearable devices. More particularly, but not exclusively, the present invention relates to earpieces.

### BACKGROUND

Wearable devices such as earpieces are small devices. Yet, there is a need to increase the functionality of these type of devices through inclusion of additional components. Therefore, there are significant constraints on the space available including constraints on the overall size of the housing of the device and constraints on the available printed circuit board space. Therefore, what is needed is are innovative methods, apparatus, and systems which allow for moving component parts such as antennas off of the printed circuit board.

### SUMMARY

It is a primary object, feature, or advantage of the present invention to improve over the state of the art.

It is a further object, feature, or advantage of the present invention to allow for the printing of one or more antennas onto a wearable device without having to print them with a circuit board.

It is a still further object, feature, or advantage of the present invention to save space on a circuit board for use in small wearable devices.

In one implementation, an earpiece includes an earpiece housing having an external surface and an internal surface, a transceiver disposed within the earpiece, and at least one antenna deposited onto either the external surface or the internal surface of the earpiece housing and using vapor deposition and electrically connected to the transceiver.

One or more of the following features may be included. One or more antennas may be omnidirectional antennas. One or more antennas may be directional antennas. One or more antennas may be monopole antennas. One or more antennas may be dipole antennas. One or more antennas may be inverted-F antennas. One or more antennas may be planar inverted-F antennas. The earpiece may comprise a set of earpieces, wherein at least one antenna in a left earpiece may transmit and receive signals from at least one antenna in a right earpiece, which may transmit and receive signals from at least one antenna in the left earpiece.

In another implementation, a method for depositing a substance onto a surface of a wearable device includes loading a conductive substance into a vapor deposition system, and depositing the conductive substance onto either the external surface or the internal surface of the wearable device using the vapor deposition system to create an antenna pattern.

One or more of the following features may be included. The wearable device may be an earpiece, which comprises a processor disposed within the earpiece, which may further comprise an output device, a microphone, a transceiver, a sensor, an LED display, a battery, a gesture control interface, or a camera. The conductive substance may be a metallic substance. The vapor deposition system may be a physical deposition system. The deposition of the conductive substance to create an antenna may operatively connect the transceiver to the antenna. One or more antennas may be omnidirectional antennas. One or more antennas may be directional antennas. One or more antennas may be monopole antennas. One or more antennas may be dipole antennas. One or more antennas may be inverted-F antennas. One or more antennas may be planar inverted-F antennas.

One or more of these and/or other objects, features, or advantages of the present invention will become apparent from the specification and claims that follow. No single embodiment need provide each and every object, feature, or advantage. Different embodiments may have different objects, features, or advantages. Therefore, the present invention is not to be limited to or by any object, feature, or advantage stated herein.

### BRIEF DESCRIPTION OF THE DRAWINGS

FIG. 1 is a block diagram of one embodiment of an earpiece with printed antenna.

FIG. 2 is a block diagram of a printed antenna on an internal surface of an earpiece.

FIG. 3 includes a left earpiece and a right earpiece with antenna attached on an external surface of each.

FIG. 4 illustrates a flowchart of one implementation of a method of depositing a substance onto a surface of a wearable device.

FIG. 5 illustrates a flowchart of a second embodiment of the method of depositing a substance onto a surface of a wearable device.

### DETAILED DESCRIPTION

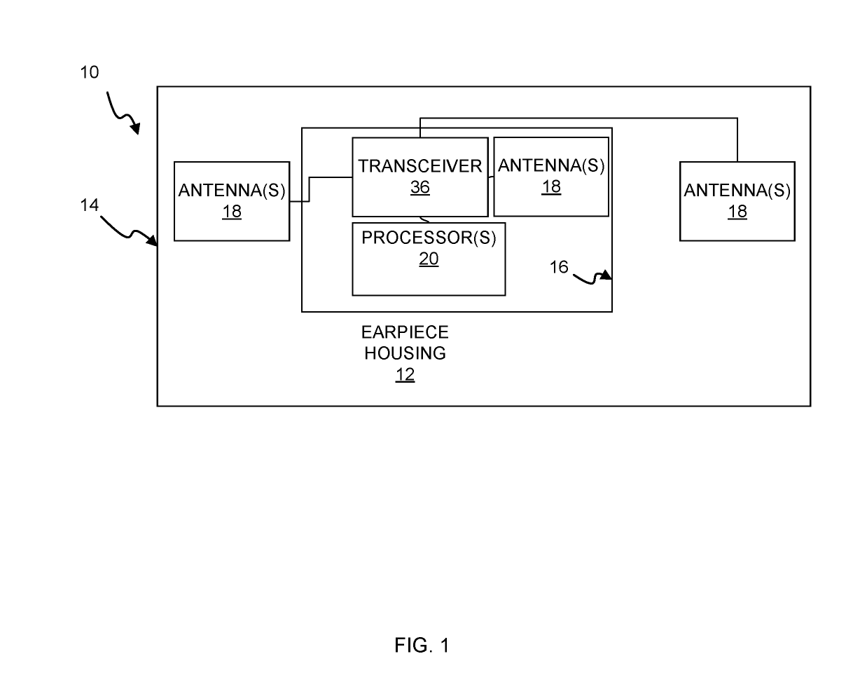

FIG. 1 shows a block diagram of the earpiece 10. One or more antennas 18 are deposited onto an external surface 14 of the earpiece housing 12 and/or an internal surface 16 of the earpiece housing 12, with each antenna 18 operatively connected to at least one transceiver 36 disposed within the earpiece 10. Each antenna 18 may be deposited onto the earpiece housing 12 using a vapor deposition process and each antenna 18 may be operatively connected to one or more transceivers 36 which may be operatively connected to one or more processors 20. More than one antenna 18 may be present on the external surface 14 and/or the internal surface 16 of the earpiece housing 12. In addition, more than one type of antenna 18 may be deposited onto the earpiece surface 12. For example, one or more antennas 18 may be inverted-F antennas, inverted-L antennas, planar inverted-F antennas, microstrip antennas, or any other types of antennas or antenna patterns or designs suitable for a wireless device. Also, each antenna 18 deposited onto the earpiece housing 12 may be configured to operate at differing frequencies. For example, an earpiece 10 may have one or more antennas 18 attuned to Global Positioning System (GPS) frequencies or wavelengths, one or more antennas 18 attuned to Worldwide Interoperability for Microwave Access (WiMAX) frequencies or wavelengths, one or more antennas 18 attuned to Long Term Evolution (LTE) frequencies, one or more antennas 18 attuned to WiFi frequencies or wavelengths, one or more antennas 18 attuned to Bluetooth or Bluetooth Low Energy (BLE) frequencies or wavelengths or any number of antennas 18 attuned to various frequencies/wavelengths or standards. The various examples previously mentioned should not be taken to be exclusive. It is also to be understood that a single antenna may be used for different frequencies or wavelengths.

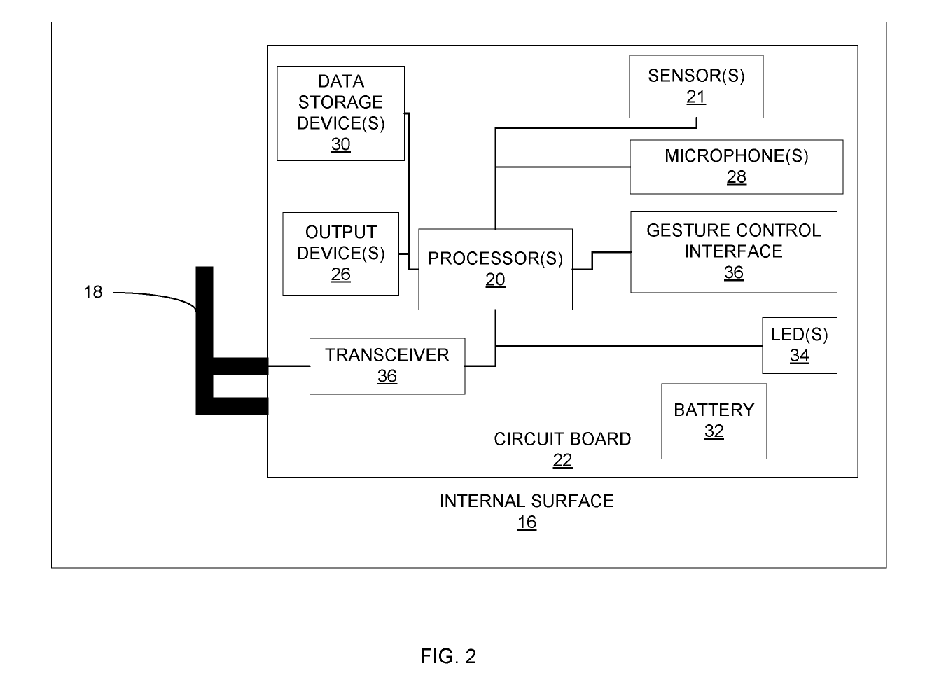

FIG. 2 illustrates an antenna 18 deposited onto an internal surface 16 of an earpiece housing 12 and operatively connected with a processor 20 located on a circuit board 22. The antenna 18 is electrically connected to a transceiver 36 which is connected to a processor 20. The antenna may be an omnidirectional antenna, a directional antenna, a monopole antenna, a dipole antenna, an inverted-F antenna, a planar inverted-F antenna, or any number of different types of antennas suitable for receiving electromagnetic signals. The antenna shown in FIG. 2 is a type of planar inverted-F antenna, one example of antenna which may be used for an earpiece or other wearable device. The deposition of the antenna 18 may be by physical or chemical vapor deposition.

As shown in FIG. 2 various other components are present. For example, one or more sensors 21 may be operatively connected to one or more processors 20. Examples of sensors may include biometric or physiological sensors, inertial sensors, or other types of sensors. One or more data storage devices 30 may be operatively connected to one or more processors 30. One or more output devices 26 may be operatively connected to one or more processor's 26 such as speakers. One or more microphones 28 may be operatively connected to one or more processors 20. A gesture control interface 36 may be operatively connected to one or more processors 20. The gestural control interface 36 may be optical, capacitive, or otherwise and may include one or more emitters and one or more detectors. One or more LEDs 34 may be operatively connected to one or more processors 20. A battery 32 may be present as well. Note that where the size of the housing and the available board space are limited, it may be difficult to include all desired components on the circuit board or within the housing. Thus, depositing the antenna 18 on the surface of the housing (inner or outer) is advantageous as it frees up additional space which may be otherwise utilized or which may allow for the size of the earpiece (or other wearable device) to be reduced.

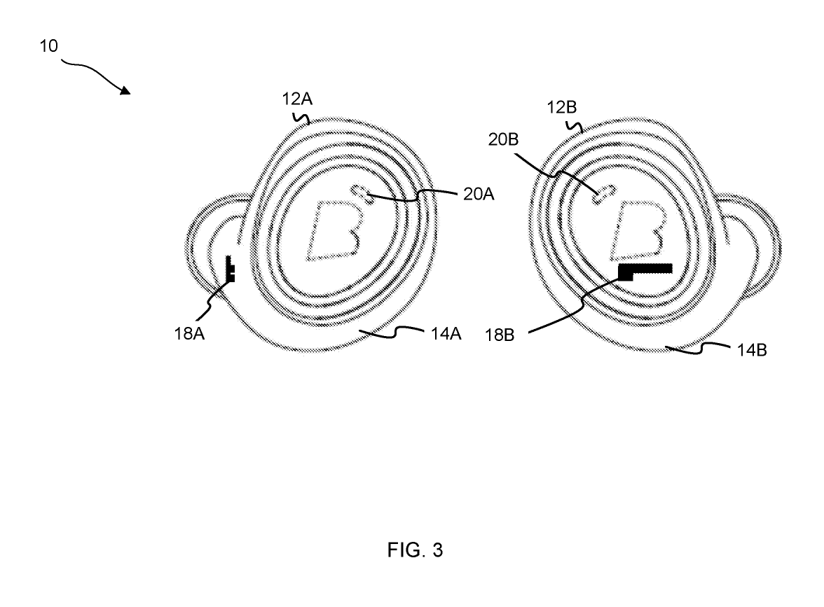

FIG. 3 illustrates a set of earpieces 10 with antenna 18A and 18B attached to the external surfaces 14A and 14B of earpiece housings 12A and 12B. The antenna 18A, 18B, as illustrated, may be located anywhere on an external surface of an earpiece housing and may be of any size or any shape or pattern. The set of earpieces 10 may be configured to either fit into a user's ear canal in an ear bud style configuration so as to minimize the amount of external sound capable of reaching the ear canal or configured to fit within the ear canal so as to minimize the distance between the speakers and a user's tympanic membranes. Microphones 20A and 20B are also shown. Any number of microphones may be present.

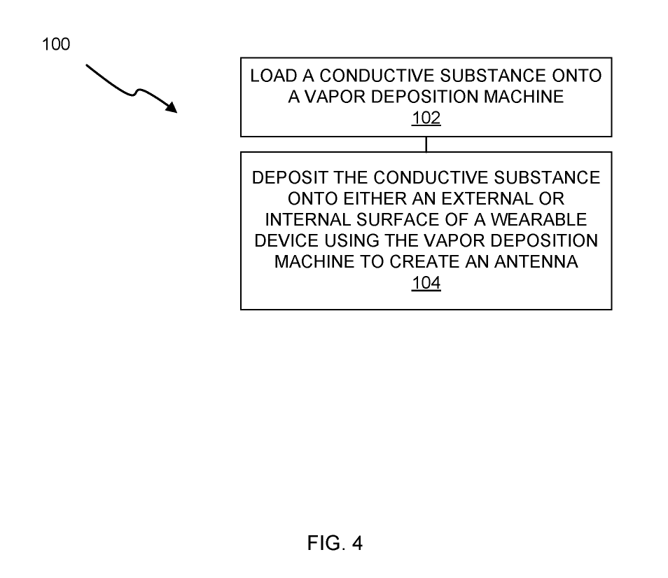

FIG. 4 illustrates one example of the method of depositing a substance onto a surface of a wearable device 100. First, in step 102, the conductive substance is loaded onto a vapor deposition machine. The conductive substance may be metallic, and the vapor deposition machine may be loaded by a user, a third party, or another machine. The vapor deposition machine, in step 104, then deposits an antenna onto an exterior or interior surface of a wearable device using the conductive substance. The wearable device may be one or more earpieces, one or more watches, one or more rings, one or more necklaces, one or more bracelets, one of more pieces of headwear, a pair of glasses, one or more contact lenses, or one or more items of jewelry or clothing not previously mentioned. The antenna deposited onto a surface of the wearable device may an inverted-F antenna, a planar inverted-F antenna, an inverted-L antenna, a quarter-wave monopole antenna, a microstrip antenna, or any other type of antenna capable of receiving radio and other electromagnetic waves. The deposition may be performed atom-by-atom or molecule-by-molecule, and may be performed on a wearable device with other components pre-installed or on a wearable device without any components installed. In other words, the deposition of the antenna may come at any point during the creation of the full wearable device.

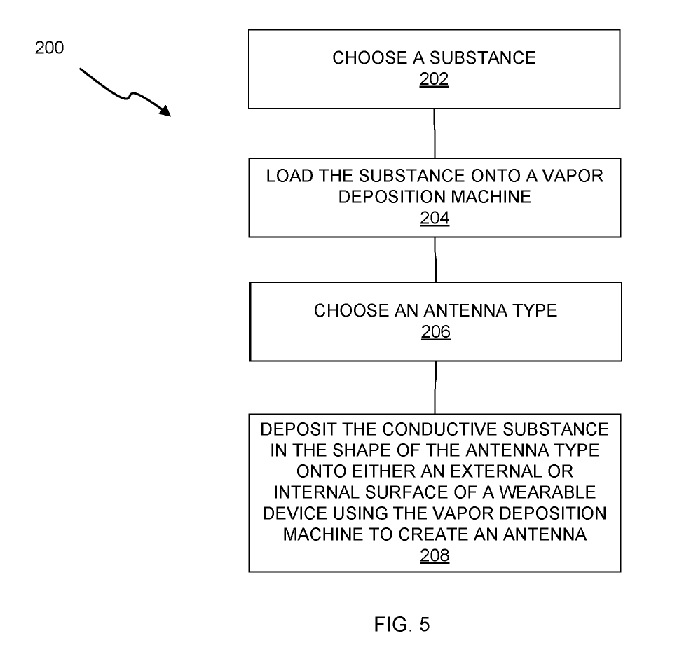

FIG. 5 illustrates another example of the method of depositing a substance onto a surface of a wearable device 200. First, in step 202, a user selects the substance to be used to create the antenna. The substance should preferably be a substance which conducts electricity well. Also, the substance may be a mixture of two or more substances and the substance itself does not need to be uniform so long as the substance meets the functional requirements of each antenna. The user, in step 204, then instructs a machine to load the substance for use in printing the antenna with a vapor deposition machine. The loading may be performed by the vapor deposition machine, another machine operably connected to the vapor deposition machine, or another machine near the vapor deposition machine. The user, in step 206, then selects the type of antenna to be printed onto a surface of the earpiece housing. The user may select from any number of types of antenna, including inverted-F antennas, inverted-L antennas, planar inverted-F antennas, microstrip antennas, or any other types of antennas suitable for a wireless device. The vapor deposition machine, in step 208, then deposits the antenna onto a surface of a wearable device. The process may take any reasonable amount of time, and the vapor deposition may be performed physically or chemically. The vapor deposition machine may also deposit more than one antenna per loading, and does not need to print each antenna on the same wearable device. Also, each antenna may be operatively connected to one or more components present in the earpiece in any number of ways.

Therefore, various examples of apparatus, methods, and systems have been shown and described. Although specific embodiments are provided, the present invention is not to be limited by or to the specific examples disclosed herein as various options and alternatives are contemplated.

What is claimed is:

1. An earpiece comprising:
an earpiece housing having an external surface and an internal surface;
a transceiver disposed within the earpiece; and
an antenna deposited onto a surface of the earpiece housing and operatively connected to the transceiver, wherein the antenna is deposited onto the surface of the earpiece housing using a vapor deposition process.

2. The earpiece of claim 1 wherein the antenna is selected from a group consisting of an omnidirectional antenna, a directional antenna, a monopole antenna, a dipole antenna, an inverted-F antenna, and a planar inverted-F antenna.

3. The earpiece of claim 1 wherein the earpiece is a left earpiece within a set of earpieces comprising the left earpiece and a right earpiece.

4. The earpiece of claim 1 wherein the surface is an internal surface of the earpiece housing.

5. The earpiece of claim 1 wherein the surface is an external surface of the earpiece housing.

6. The earpiece of claim 1 further comprising a processor disposed within the earpiece and operatively connected to the transceiver, and a gestural interface operatively connected to the processor.

7. The earpiece of claim 1 further comprising at least one speaker and at least one microphone within the earpiece housing.

8. A method of manufacturing a wearable device comprising:
loading a conductive substance into a vapor deposition system; and
depositing the conductive substance onto a surface of a wearable device using the vapor deposition system to form an antenna pattern.

9. The method of claim 8 wherein the wearable device is an earpiece.

10. The method of claim 9 further comprising connecting the antenna pattern to a transceiver of the earpiece.

11. The method of claim 10 wherein at least one earpiece further comprises at least one additional component selected from a group consisting of an output device, a microphone, a processor, a sensor, an LED display, a battery, a gesture control interface, and a camera.

12. The method of claim 8 wherein the conductive substance is a metallic substance.

13. The method of claim 8 wherein the vapor deposition system is a physical vapor deposition system.

14. The method of claim 13 wherein the antenna pattern is selected from a set consisting of an omnidirectional antenna pattern, a directional antenna pattern, a monopole antenna pattern, a dipole antenna pattern, and an inverted-F antenna.

15. The method of claim 13 wherein the antenna pattern is an planar inverted-F antenna pattern.
